(19) United States
(12) Patent Application Publication
(10) Pub. No.: US 2016/0088728 A1
(43) Pub. Date: Mar. 24, 2016

(54) INSULATION FILM OF A SIGNAL TRANSMISSION LINE AND SIGNAL TRANSMISSION LINE COMPRISING THE SAME

(71) Applicant: TAIFLEX Scientific Co., Ltd., Kaohsiung (TW)

(72) Inventors: Fu-Min Wang, KAOHSIUNG (TW); Tsung-Tai Hung, KAOHSIUNG (TW); I-Ling Teng, KAOHSIUNG (TW); Feng-Jung Tien, KAOHSIUNG (TW); Yu-Hsien Lee, KAOHSIUNG (TW); Tzu-Ching Hung, KAOHSIUNG (TW)

(21) Appl. No.: 14/530,833

(22) Filed: Nov. 3, 2014

(30) Foreign Application Priority Data
Sep. 19, 2014 (TW) 103132506

(51) Int. Cl. H05K 1/03; H05K 1/02

(52) U.S. Cl. CPC H05K 1/036; H05K 1/0237

(57) ABSTRACT

An insulation film of a signal transmission line includes a substrate layer, and a bonding layer arranged on the substrate layer for directly covering metal conductors of the signal transmission line, wherein the bonding layer is made of a polyolefin copolymer resin or a polyolefin resin mixture.

### BACKGROUND OF THE INVENTION

1. Field of the Invention

The present invention relates to an insulation film of a signal transmission line and a signal transmission line comprising the insulation film, and more particularly, to an insulation film of a signal transmission line and a signal transmission line comprising the insulation film capable of improving high frequency signal transmission efficiency.

2. Description of the Prior Art

In recent years, flex flat cables are utilized in car navigation systems, flat display devices, computer motherboards and other electronic devices for transmitting high frequency signals. Generally, a flex flat cable comprises a plurality of metal wires and a pair of insulation films covering the metal wires. Dielectric constant and dissipation factor of the insulation film may affect characteristic impedance of the flex flat cable, such that transmission efficiency of the flex flat cable is affected as well. For example, when the dielectric constant of the insulation film is higher, signal transmission delay of the high frequency signals is more; and when the dissipation factor of the insulation film is higher, signal loss of the high frequency signals is larger. In order to reduce the signal transmission delay and the signal loss when transmitting the high frequency signals, the insulation film covering the metal wires must have a lower dielectric constant and a lower dissipation factor.

However, in the prior art, most of the flex flat cables have insulation films with bonding layers made of a polyester resin, where the polyester resin has a higher dielectric constant and a higher dissipation factor. Therefore, the flex flat cable of the prior art has bad signal transmission efficiency when transmitting the high frequency signals.

### SUMMARY OF THE INVENTION

The present invention provides an insulation film of a signal transmission line and a signal transmission line comprising the insulation film capable of improving high frequency signal transmission efficiency, in order to solve problems of the prior art.

The insulation film of the present invention comprises a substrate layer, and a bonding layer arranged on the substrate layer, for directly covering metal conductors of the signal transmission line, wherein the bonding layer is made of a polyolefin copolymer resin or a polyolefin resin mixture.

The signal transmission line of the present invention comprises a plurality of metal conductors, a first insulation film and a second insulation film. The plurality of metal conductors are arranged at intervals. The first insulation film comprises a first substrate layer, and a first bonding layer arranged on the first substrate layer, for directly covering a first side of each of the metal conductors. The second insulation film comprises a second substrate layer, and a second bonding layer arranged on the second substrate layer, for directly covering a second side of each of the metal conductors opposite to the first side. Wherein, the first bonding layer and the second bonding layer are made of a polyolefin copolymer resin or a polyolefin resin mixture.

In contrast to the prior art, the bonding layer of the insulation film of the present invention is made of the polyolefin copolymer resin or the polyolefin resin mixture, such that the insulation film of the present invention has a lower dielectric constant and a lower dissipation factor. When the insulation film of the present invention is applied to the signal transmission line, the signal transmission line has less signal transmission delay and smaller signal loss when transmitting high frequency signals, so as to improve high frequency signal transmission efficiency of the signal transmission line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing an insulation film of a signal transmission line of the present invention.

FIG. 2 is a diagram illustrating a manufacturing method of a signal transmission line of the present invention.

FIG. 3 is a diagram showing a signal transmission line according to a first embodiment of the present invention.

FIG. 4 is a diagram showing a signal transmission line according to a second embodiment of the present invention.

### DETAILED DESCRIPTION

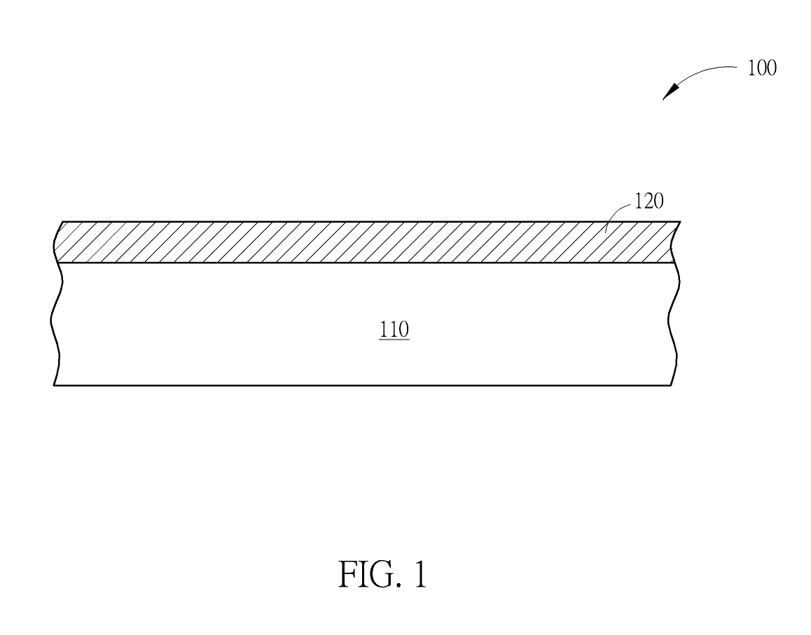

Please refer to FIG. 1. FIG. 1 is a diagram showing an insulation film of a signal transmission line of the present invention. As shown in FIG. 1, the insulation film 100 of the signal transmission line of the present invention includes a substrate layer 110 and a bonding layer 120. The substrate layer can be made of polyethylene terephthalate (PET), polyethylene naphthalate (PEN), polyphenylene Sulfide (PPS), polyimide (PI) or polyamides (PA) materials. The substrate layer 110 has a thickness between 4 micrometers and 100 micrometers, and in a preferred embodiment, the thickness of the substrate layer 110 is between 12 micrometers and 75 micrometers. The bonding layer 120 is arranged on the substrate layer 110, and the bonding layer 120 is configured to directly cover metal conductors of the signal transmission line. In addition, at least one surface treating layer can be further arranged on the substrate layer 110, in other words, the insulation film 100 can further comprises at least one surface treating layer between the substrate layer 110 and the bonding layer 120. The bonding layer 120 is made of a polyolefin copolymer resin or a polyolefin resin mixture. Since the polyolefin copolymer resin and the polyolefin resin mixture have characteristics of low dielectric constant and low dissipation factor, when the insulation film 100 of the present invention is applied to the signal transmission line, signal transmission efficiency of the signal transmission line can be improved when transmitting high frequency signals.

In order to increase bonding strength of the bonding layer, the bonding layer 120 of the insulation film 100 of the present invention can be made of an ethylene copolymer resin. For example, in a first embodiment of the insulation film 100 of the present invention, the bonding layer 120 is made of an ethylene-vinyl acetate copolymer resin. In order to increase flame resistance of the insulation film 100, the bonding layer 120 can further comprise a flame retardant, such as a phosphorus-based flame retardant, and a weight ratio of the ethylene-vinyl acetate copolymer resin to the phosphorus-based flame retardant is 100:10. After the ethylene-vinyl acetate copolymer resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and signal transmission frequency is 10 GHz, the dielectric constant (Dk) of the bonding layer 120 is 2.52, and the dissipation factor (Df) of the bonding layer 120 is 0.0057.

In a second embodiment of the insulation film 100 of the present invention, the bonding layer 120 is made of an ethylene-acrylic acid copolymer resin. In order to increase flame resistance of the insulation film 100, the bonding layer 120 can further comprise a flame retardant, such as a phosphorus-based flame retardant, and a weight ratio of the ethylene-acrylic acid copolymer resin to the phosphorus-based flame retardant is 100:10. After the ethylene-acrylic acid copolymer resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.41, and the dissipation factor (Df) of the bonding layer 120 is 0.0012.

In a third embodiment of the insulation film 100 of the present invention, the bonding layer 120 is made of an ethylene-methyl methacrylate copolymer resin. In order to increase flame resistance of the insulation film 100, the bonding layer 120 can further comprise a flame retardant, such as a phosphorus-based flame retardant, and a weight ratio of the ethylene-methyl methacrylate copolymer resin to the phosphorus-based flame retardant is 100:10. After the ethylene-methyl methacrylate copolymer resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.47, and the dissipation factor (Df) of the bonding layer 120 is 0.0156.

In a fourth embodiment of the insulation film 100 of the present invention, the bonding layer 120 is made of an ethylene-glycidyl methacrylate copolymer resin. In order to increase flame resistance of the insulation film 100, the bonding layer 120 can further comprise a flame retardant, such as a phosphorus-based flame retardant, and a weight ratio of the ethylene-glycidyl methacrylate copolymer resin to the phosphorus-based flame retardant is 100:10. After the ethylene-glycidyl methacrylate copolymer resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.59, and the dissipation factor (Df) of the bonding layer 120 is 0.0318.

In order to prevent occurrence of chemical reaction between the bonding layer 120 and the metal conductors, for increasing stability of the signal transmission line, the bonding layer 120 of the insulation film 100 of the present invention can be made of an ethylene-maleic anhydride copolymer resin. For example, in a fifth embodiment of the insulation film 100 of the present invention, the bonding layer 120 is made of the ethylene-maleic anhydride copolymer resin. In order to increase flame resistance of the insulation film 100, the bonding layer 120 can further comprise a flame retardant, such as a phosphorus-based flame retardant, and a weight ratio of the ethylene-maleic anhydride copolymer resin to the phosphorus-based flame retardant is 100:10. After the ethylene-maleic anhydride copolymer resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.20, and the dissipation factor (Df) of the bonding layer 120 is 0.0008.

In addition, the bonding layer 120 of the insulation film 100 of the present invention can also be made of a mixture of the ethylene-maleic anhydride copolymer resin and a low-density polyethylene resin. For example, in a sixth embodiment of the insulation film 100 of the present invention, a weight ratio of the ethylene-maleic anhydride copolymer resin to the low-density polyethylene resin to the phosphorus-based flame retardant in the bonding layer 120 is 20:80:10. After the ethylene-maleic anhydride copolymer resin, the low-density polyethylene resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.32, and the dissipation factor (Df) of the bonding layer 120 is 0.0006.

In a seventh embodiment of the insulation film 100 of the present invention, a weight ratio of the ethylene-maleic anhydride copolymer resin to the low-density polyethylene resin to the phosphorus-based flame retardant in the bonding layer 120 is 50:50:10. After the ethylene-maleic anhydride copolymer resin, the low-density polyethylene resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.29, and the dissipation factor (Df) of the bonding layer 120 is 0.0006.

In an eighth embodiment of the insulation film 100 of the present invention, a weight ratio of the ethylene-maleic anhydride copolymer resin to the low-density polyethylene resin to the phosphorus-based flame retardant in the bonding layer 120 is 80:20:10. After the ethylene-maleic anhydride copolymer resin, the low-density polyethylene resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.19, and the dissipation factor (Df) of the bonding layer 120 is 0.0007.

In the sixth to eighth embodiments of the insulation film of the present invention, a weight ratio of the ethylene-maleic anhydride copolymer resin to the low-density polyethylene resin is between 0.25 and 4, and the low-density polyethylene resin can be replaced by a linear low-density polyethylene resin.

On the other hand, a ratio of the flame retardant in the bonding layer 120 can be adjusted according to requirements. A weight ratio of the flame retardant to the polyolefin copolymer resin or the polyolefin resin mixture is between 0.1 and 0.8. For example, in a ninth embodiment of the insulation film 100 of the present invention, a weight ratio of the ethylene-maleic anhydride copolymer resin to the linear low-density polyethylene resin to the phosphorus-based flame retardant in the bonding layer 120 is 50:50:30. After the ethylene-maleic anhydride copolymer resin, the linear low-density polyethylene resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.11, and the dissipation factor (Df) of the bonding layer 120 is 0.0008.

In a tenth embodiment of the insulation film 100 of the present invention, a weight ratio of the ethylene-maleic anhydride copolymer resin to the linear low-density polyethylene resin to the phosphorus-based flame retardant in the bonding layer 120 is 50:50:50. After the ethylene-maleic anhydride copolymer resin, the linear low-density polyethylene resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.37, and the dissipation factor (Df) of the bonding layer 120 is 0.0012.

In an eleventh embodiment of the insulation film 100 of the present invention, a weight ratio of the ethylene-maleic anhydride copolymer resin to the linear low-density polyethylene resin to the phosphorus-based flame retardant in the bonding layer 120 is 50:50:80. After the ethylene-maleic anhydride copolymer resin, the linear low-density polyethylene resin and the phosphorus-based flame retardant are mixed and granulated, the above material can be used to form a film-like bonding layer 120 with a predetermined thickness, and the bonding layer 120 is further combined with the substrate layer 110. Through actual measurement, when the thickness of the bonding layer 120 is 30 micrometers and the signal transmission frequency is 10 GHz, the dielectric constant (Dk) of the bonding layer 120 is 2.12, and the dissipation factor (Df) of the bonding layer 120 is 0.0012.

The first embodiment to the eleventh embodiment of the insulation film 100 of the present invention are illustrated as examples, ingredients and forming ratios of the insulation film 100 of the present invention are not limited to the above embodiments. Moreover, in the embodiments of the insulation film 100 of the present invention, it is not necessary to add the flame retardant.

In the prior art, when a weight ratio of the polyester resin to the phosphorus-based flame retardant in the bonding layer, which has a thickness of 30 micrometers, is 100:10 and the signal transmission frequency is 10 GHz, the dielectric constant (Dk) of the bonding layer of the prior art is 3.1, and the dissipation factor of the bonding layer of the prior art is 0.015. All of the dielectric constants in the embodiments of the insulation film of the present invention are smaller than the dielectric constant of the bonding layer of the prior art, and most of the dissipation factors in the embodiments of the insulation film of the present invention are smaller than the dissipation factor of the bonding layer of the prior art. Therefore, when the insulation film 100 of the present invention is applied to the signal transmission line, the signal transmission efficiency of the signal transmission line can be improved when transmitting high frequency signals. Especially, when the bonding layer 120 comprises the ethylene-maleic anhydride copolymer resin, the bonding layer 120 not only has a lower dielectric constant and a lower dissipation factor, but also has stronger bonding strength. Moreover, the chemical reaction between the bonding layer and the metal conductor is not easy to occur, so as to increase stability of the signal transmission line.

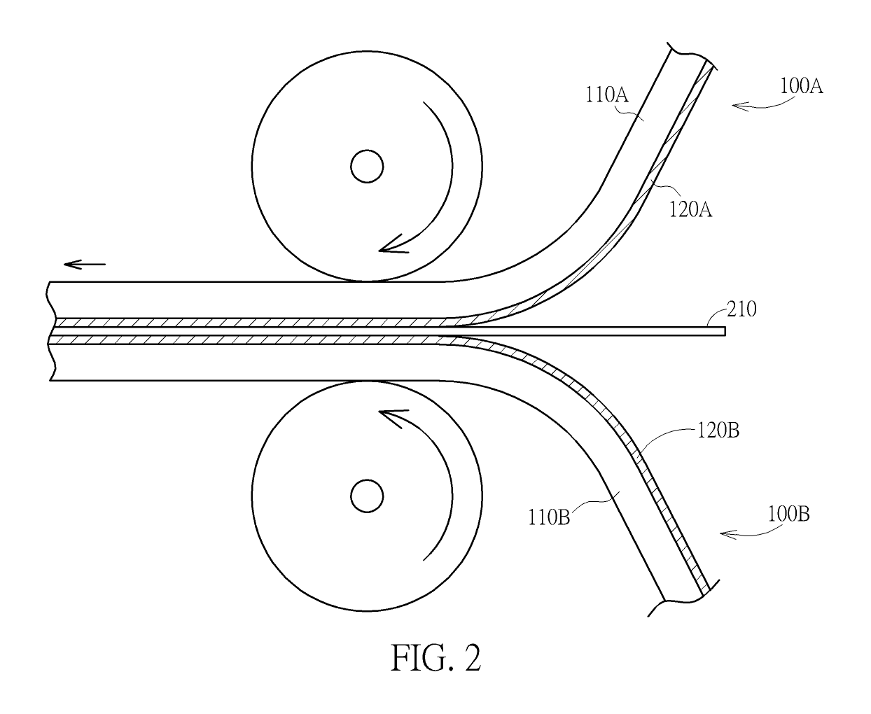

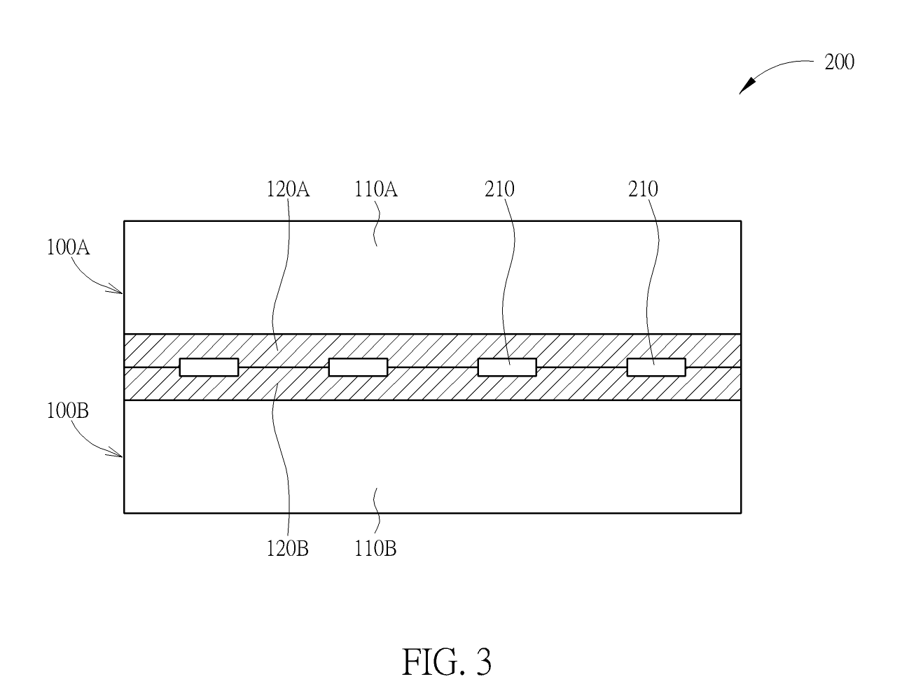

Please refer to FIG. 2 and FIG. 3. FIG. 2 is a diagram illustrating a manufacturing method of a signal transmission line of the present invention. FIG. 3 is a diagram showing a signal transmission line according to a first embodiment of the present invention. As shown in figures, the signal transmission line 200 of the present invention comprises a plurality of metal conductors 210, a first insulation film 100A and a second insulation film 100B. The plurality of metal conductors 210 are arranged at intervals. The first insulation film 100A comprises a first substrate layer 110A and a first bonding layer 120A. The second insulation film 100B comprises a second substrate layer 110B and a second bonding layer 120B. The first insulation film 100A and the second insulation film 100B are identical to the insulation film 100 of FIG. 1, and the first insulation film 100A and the second insulation film 100B are not limited to the first to eleventh embodiments of the insulation film of the present invention. The first insulation film 100A and the second insulation film 100B are combined by thermo-compression bonding for further covering the plurality of metal conductors 210. During the thermo-compression bonding, the first insulation film 100A and the second insulation film 100B are bonded together, and the first bonding layer 120A and the second bonding layer 120B directly cover a first side and a second side of each of the metal conductors 210 respectively.

According to the above arrangement, since the first bonding layer 120A and the second bonding layer 120B have lower dielectric constants and lower dissipation factors, the signal transmission line has less signal transmission delay and smaller signal loss when transmitting high frequency signals. Therefore, the signal transmission line 200 of the present invention has better high frequency signal transmission efficiency. Moreover, when the first bonding layer 120A and the second bonding layer 120B comprise the ethylene-maleic anhydride copolymer resin, the first bonding layer 120A and the second bonding layer 120B have stronger bonding strength. Furthermore, the chemical reaction between the first bonding layer 120A and the metal conductor 210 or between the second bonding layer 120B and the metal conductor 210 is not easy to occur, so as to increase stability of the signal transmission line 200.

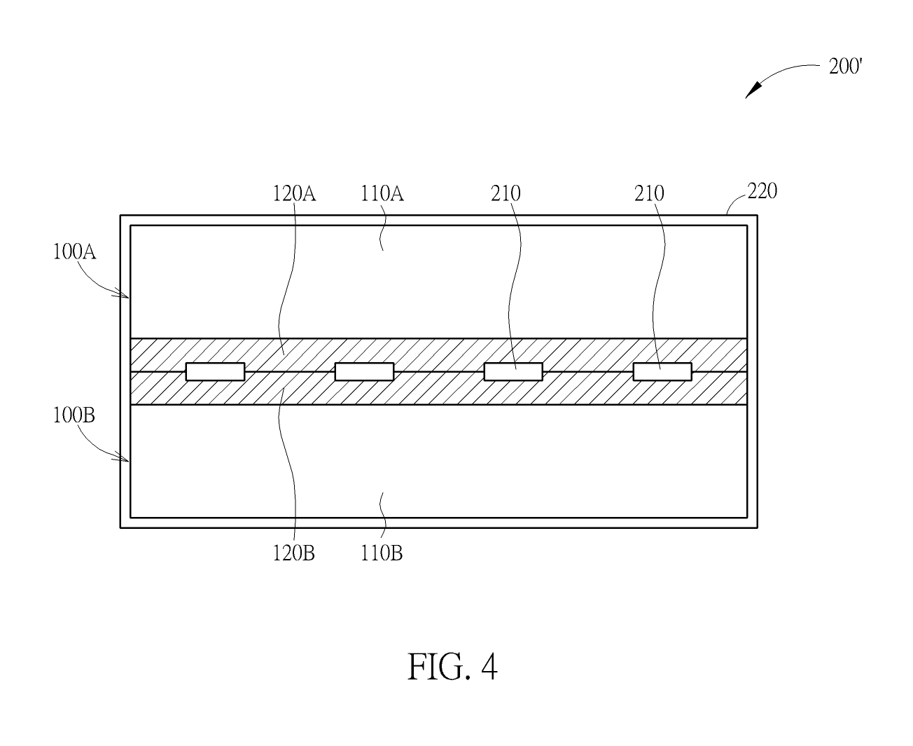

Please refer to FIG. 4. FIG. 4 is a diagram showing a signal transmission line according to a second embodiment of the present invention. As shown in FIG. 4, in addition to a plurality of metal conductors 210, a first insulation film 100A and a second insulation film 100B, the signal transmission line 200′ of the present invention further comprises a shielding layer 220 for covering the first insulation film 100A and the second insulation film 100B. Thereby, the signal transmission line 200′ of the present invention can further prevent electromagnetic interference.

In addition, the present invention is not limited to the manufacturing method of the signal transmission line in FIG. 2. The manufacturing method of the signal transmission line in FIG. 2 is applicable to a flex flat cable (FFC). In other embodiment of the present invention, the signal transmission line 200, 200′ can also be a flexible printed circuit board. For example, the present invention can first attach a metal foil (such as a copper foil) on the first bonding layer 120A of the first insulation film 100A, and then the metal foil is etched according to circuit design for forming the metal conductors 210. Thereafter, the first insulation film 100A and the second insulation film 100B are further combined by the thermo-compression bonding for forming the signal transmission line 200, 200′.

In contrast to the prior art, the bonding layer of the insulation film of the present invention is made of the polyolefin copolymer resin or the polyolefin resin mixture, such that the insulation film of the present invention has a lower dielectric constant and a lower dissipation factor. When the insulation film of the present invention is applied to the signal transmission line, the signal transmission line has less signal transmission delay and smaller signal loss when transmitting high frequency signals, so as to improve high frequency signal transmission efficiency of the signal transmission line.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An insulation film of a signal transmission line, comprising:
a substrate layer; and
a bonding layer, arranged on the substrate layer, for directly covering metal conductors of the signal transmission line;
wherein the bonding layer is made of a polyolefin copolymer resin or a polyolefin resin mixture.

2. The insulation film of claim 1, wherein the bonding layer is made of an ethylene copolymer resin.

3. The insulation film of claim 2, wherein the bonding layer is made of an ethylene-maleic anhydride copolymer resin.

4. The insulation film of claim 1, wherein the bonding layer is made of a mixture of an ethylene-maleic anhydride copolymer resin and a low-density polyethylene resin.

5. The insulation film of claim 4, wherein a weight ratio of the ethylene-maleic anhydride copolymer resin to the low-density polyethylene resin is between 0.25 and 4.

6. The insulation film of claim 1, wherein the bonding layer further comprises a flame retardant.

7. The insulation film of claim 6, wherein the flame retardant is a phosphorus-based flame retardant, and a weight ratio of the flame retardant to the polyolefin copolymer resin or the polyolefin resin mixture is between 0.1 and 0.8.

8. A signal transmission line, comprising:
a plurality of metal conductors, arranged at intervals;
a first insulation film, comprising:
a first substrate layer; and
a first bonding layer, arranged on the first substrate layer, for directly covering a first side of each of the metal conductors; and
a second insulation film, comprising:
a second substrate layer; and
a second bonding layer, arranged on the second substrate layer, for directly covering a second side of each of the metal conductors opposite to the first side;
wherein the first bonding layer and the second bonding layer are made of a polyolefin copolymer resin or a polyolefin resin mixture.

9. The signal transmission line of claim 8, wherein the first bonding layer and the second bonding layer are made of an ethylene copolymer resin.

10. The signal transmission line of claim 9, wherein the first bonding layer and the second bonding layer are made of an ethylene-maleic anhydride copolymer resin.

11. The signal transmission line of claim 8, wherein the first bonding layer and the second bonding layer are made of a mixture of an ethylene-maleic anhydride copolymer resin and a low-density polyethylene resin.

12. The signal transmission line of claim 11, wherein a weight ratio of the ethylene-maleic anhydride copolymer resin to the low-density polyethylene resin is between 0.25 and 4.

13. The signal transmission line of claim 8, wherein the first bonding layer and the second bonding layer further comprise a flame retardant.

14. The signal transmission line of claim 13, wherein the flame retardant is a phosphorus-based flame retardant, and a weight ratio of the flame retardant to the polyolefin copolymer resin or the polyolefin resin mixture is between 0.1 and 0.8.

15. The signal transmission line of claim 8 further comprising a shielding layer for covering the first insulation film and the second insulation film.
